(19) United States
(12) Patent Application Publication
(10) Pub. No.: US 2026/0313859 A1
(43) Pub. Date: Oct. 8, 2026

(54) COOLING DEVICE FOR COOLING ELECTRONIC COMPONENTS

(71) Applicant: Semikron Danfoss GmbH, Flensburg (DE)

(72) Inventor: Klaus Olesen, Sønderborg (DK)

(21) Appl. No.: 19/482,091

(22) PCT Filed: May 8, 2024
(86) PCT No.: PCT/EP2024/062816

§ 371 Date: Nov. 6, 2025

(30) Foreign Application Priority Data
May 9, 2023 (DK) PA202330018

(51) Int. Cl. H05K 7/20

(52) U.S. Cl. CPC H05K 7/20927; H05K 7/20254

(57) ABSTRACT

For efficient cooling of electronic components, in particular power electronics in an electric vehicle, electronic components are provided on a first coolant chamber wall (2A) of a cooling device (1, 100). The cooling device has two inner coolant volumes (10A, 10B) separated by a separation wall (5), each coolant volume (10A, 10B) containing a coolant flow structure (7A, 7B) with undulating channels (14A, 14B). The separation wall (5) has multiple openings (6) for providing coolant flow back and forth between the two coolant volumes (10A, 10B) while the propagates alternatingly through both coolant flow structures (7A, 7B) from a first end (11) to a second end (12) of the flow structures (7A, 7B), and similarly in opposite direction, in order to achieve proper mixing of the coolant and a homogeneous temperature profile along the first coolant chamber wall (2A).

### CROSS-REFERENCE TO RELATED APPLICATIONS

This application is a National Stage application of International Patent Application No. PCT/EP2024/062816, filed on May 8, 2024, which claims priority to Danish Patent Application No. PA202330018, filed May 9, 2023, each of which is hereby in-corporated by reference in its entirety.

### TECHNICAL FIELD

The present invention relates to cooling device for cooling electronic components, use thereof for an electric vehicle and a method for its operation. In particular, it relates to a cooling device according to the preamble of the independent claim.

### BACKGROUND

In electric vehicles, the available power for propulsion is regulated in modules that contain power converters, switches, and regulators, which are subject to heating and which must be cooled in order to avoid damage. Especially during accelerations, electric vehicles, EV, need power in excess of 100 kW, for example up to 500 kw as in popular EV models at the time of filing of this application, and although only a small percentage of this power is converted to heat in the electronic power control system, the heat created in the electronic system can be as much as several kW, and with a local power density of more than 500 W/cm², which is substantial. To give an impression of this power, it is put forward that this power density is more than what a kitchen cooking plate produces. This heat has to be removed efficiently from the electronics in order to prevent damage by overheating. Accordingly, cooling of the electronics is a serious issue in EVs.

This issue is discussed in detail in U.S. Pat. No. 10,674,628, disclosing a cooling module for a power converter. For efficient cooling, this disclosure suggests series of identical coolant pipes that are provided side-by-side in a planar arrangement on a cooling plate that is abutting the electronics. Each coolant pipe is formed as a planar double spiral. It is explained in this disclosure that it creates an efficient cooling effect with improved uniform temperature distribution.

The system of U.S. Pat. No. 10,674,628 follows a traditional approach where thin pipes are used for transport of the coolant. However, thin pipes imply a substantial risk for clogging and stop of flow through the pipes.

Pipe systems for cooling of electronics reach back more than half a century, for example with reference to U.S. Pat. No. 4,161,980 for a double helical thyristor coolant capsule. However, apart from the risk for clogging, coolant pipe systems suffer from substantial friction through the tubing system, which reduces coolant flow, thus, going against the aim of efficient cooling.

An additional important aspect to take into account in relation to electric vehicles is the minimization of production costs. Pipes as coolant channels, especially where the pipes are provided as spirals or helices, is disadvantageous production-wise, as it implies a relatively slow and costly process. Accordingly, the systems in the disclosures U.S. Pat. Nos. 10,674,628 and 4,161,980, mentioned above, are not suitable for low-cost mass production.

Another approach for coolant channels is disclosed in Japanese patent application JP6268127A2 where a double-spiral coolant channel for cooling of electronics is provided in a block, thus, avoiding the production of pipes. However, despite the pro-duction-friendly approach as such, the long and thin coolant channel along the path through the block does not avoid the disadvantage of pressure loss in the channels which reduces flow and requires high pressure for high flow rates.

The prior art appears not to have solved the dilemma of providing uniform cooling with high coolant flow rates. Furthermore, spiral and helical paths, especially tubular flow paths, have a disadvantage in that a clogging at a single location in the path clogs the spiral or helical unit.

U.S. 5,841,634 discloses a liquid cooled heat sink in which liquid is pumped from a first lower chamber upwards through jet ports into a first upper chamber and towards the top plate that is to be cooled. The liquid then flows from the first upper chamber through a central opening into a second lower chamber, adjacent the first lower chamber, and is then pumped into a second upper chamber, adjacent the first upper chamber, and towards the top wall that is to be cooled. The liquid then flows from the second upper chamber through a further central opening into a third lower chamber, adjacent the first lower chamber, and is then pumped into a third upper chamber, adjacent the first second chamber, and towards the top wall that is to be cooled. From the third upper chamber, the fluid is drained. A disadvantage of this system is that the temperature drops from the first towards the third chamber, resulting in non-uniform cooling of the top plate.

US2022/0246495A1 discloses a heat sink for a semiconductor device, comprising a partition wall, separating two volumes with multiple groups of straight parallel flow-defining fins, arranged in multiple angles to each other. Each group has one forward flow on only one side of the partition wall and one rearward flow on only the opposite side of the partition wall. The straight flow paths, defined by the fins, cause only little turbulence, which is not optimum for cooling efficiency.

It would be desirable to provide a cooling system for electronics that do not have the disadvantages of the prior art.

### SUMMARY

It is therefore an objective of the invention to provide an improvement in the art. In particular, it is an objective to provide efficient cooling systems for electronics which are suitable for low-cost mass production, in particular in connection with electric vehicles. It is a further objective to provide a cooling module for cooling of electronics on a thermally conductive support plate in which the temperature distribution in the support plate is uniform. This objective and further advantages are achieved with a cooling device for cooling electronic components, its use and method of operation, as described below.

In short, for efficient cooling of electronic components, in particular power electronics in an electric vehicle, electronic components are provided on a first coolant chamber wall of a cooling device. The cooling device has two inner coolant volumes separated by a separation wall, each coolant volume containing a coolant flow structure with undulating channels. The separation wall has multiple openings for providing coolant flow back and forth between the two coolant volumes while the coolant propagates alternatingly through both coolant flow structures from a first end to a second end of the flow structures, and similarly in opposite direction, in order to achieve proper mixing of the coolant and a homogeneous temperature profile along the first coolant chamber wall.

Optionally, the cooling device comprises one or more cooling modules in a housing, typically also comprising a manifold for the distribution of coolant into and out of the modules. The cooling device has a coolant inlet and a coolant outlet and a coolant flow path in an inner volume of the device and through the modules, from the coolant inlet to the coolant outlet. Electronics are provided on a module wall for efficient cooling, as the electronics have thermal contact to the thermally conducting wall, for transfer of thermal energy from the electronic components through the module wall and to the circulating coolant inside the inner volume of the module.

In the following, the term wave-form is used for a structure that is repetitive alternating in a straight or bent plane, for example a zigzag-shaped structure with sharp edges or a smoothly undulating structure, such as a sine-shaped structure.

More details are explained in the following.

The cooling device is cooling electronic components in thermal contact with an outer side of a thermally conducting first coolant chamber wall. The cooling device comprises an inner volume between an inner side of the first coolant chamber wall and an opposite second coolant chamber wall. Flow paths are provided for a coolant through the inner volume for cooling the first coolant chamber wall and the electronic components by thermal energy transfer from the electronic components through the first coolant chamber wall and to the coolant on the opposite side of the first coolant chamber wall.

Optionally, the device has only one coolant chamber wall provided with electronic components, but it is also possible to provide electronic components on an outer side of the opposite wall of the device. In the following, the device is explained as having electronic components on only the first coolant chamber wall, well knowing that it, alternatively, could have electronic components additionally on an opposite second coolant chamber wall.

Inside the device, a separation wall divides the inner volume into a first and second volume on opposite sides of the separation wall. The first volume extends along the inner side of first coolant chamber wall between the separation wall and the first coolant chamber wall. The second volume extends between the separation wall and the second coolant chamber wall.

A first flow structure is provided in the first volume, only, and sealingly connected to the first side of the separation wall and to the first coolant chamber wall, and a second flow structure is provided in the second volume, only, and sealingly connected to the second side of the separation wall and to the second coolant chamber wall, so as to sealingly sandwich the separation wall by the first and second flow structures and sealingly sandwich the combination of the separation wall and the first and second flow structures by the first and second coolant chamber walls.

The flow path comprises an averaged first flow path in a first, forward direction along the first coolant chamber from a first end to a second, opposite end of the flow structures and an averaged second flow path in a second, opposite direction along the first coolant chamber wall from the second end to the first end for uniform cooling of the first coolant chamber wall by the combination of the flow of coolant along the mutually opposite first and the second flow paths.

As the coolant along the first flow path gradually takes up heat, it gets warmer on its first flow path from the first to the second end, and accordingly has a lower temperature at the first end as compared to the second end. However, on the second flow path in the opposite direction it is vice versa so that the temperature increase along the second flow path towards the first end is counteracted by the still colder coolant on the first flow path at the first end.

Especially, in first types of embodiments, where the device is provided with two coolant inlets and two coolant outlets at opposite ends, and one portion of coolant is flowing along the first flow path, and another portion of coolant is flowing in the opposite direction along the second flow path, the temperature equalisation is efficient and provides uniform cooling.

However, even in second types of embodiments where the coolant changes direction from the first flow path to the second flow path, very good results have been achieved for temperature equalisation and uniform temperature across the first coolant chamber wall with the electronic components.

In more detail, in the first types of embodiments, where the module is provided with two coolant inlets and two coolant outlets at opposite ends, a first portion of coolant is flowing from a first coolant inlet into the second (or first) volume at the first end and after flow along the first flow path leaving the first volume (or second volume) at the second end through a first coolant outlet, while a different portion of coolant is flowing from a second coolant inlet into the second (or first) volume at the second end and after flow along the second flow path leaving the first (or second) volume at the first end through a second coolant outlet. In this case, no connecting passage is provided between the first and second volume at the second end, and the separation wall at the second end is sealed by a gasket that is separating the first volume from the second volume.

For example, in the second type of embodiment, the second flow path is a continuation of the first flow path after flow from one to the other of the two volumes at the second end and change of direction of the coolant from first flow path to the second flow path towards the first end.

The first flow structure comprises an array of multiple side-by-side placed first undulating walls, each of which has an alternating wave-form with first concave portions. The array of first undulating walls in combination with the first coolant chamber wall and the separation wall define a first array of multiple undulating first channels with a corresponding alternating wave-form in the first volume.

The second flow path structure comprises an array of multiple side-by-side placed second undulating walls, each of which has an alternating wave-form with second concave portions, wherein the array of second undulating walls in combination with the second coolant chamber wall and the separation wall define a second array of multiple undulating second channels with a corresponding alternating wave-form on the separation wall in the second volume.

Each the first and second undulating walls have an averaged wave-form direction that is perpendicular to the first and second flow paths. However, the averaged wave-form direction may deviate slightly from the exact perpendicular direction, for example deviating by an angle in the range up to 10° from perpendicular, which implies an angle of 80°to 90°to the first and second flow paths. In alternative embodiments, the deviation from perpendicular is in the range of 0° to 20°, 0° to 30°, 10° to 20°, 10° to 30° or 20° to 30°.

Furthermore, the first flow structure is geometrically inverted relatively to the second flow structure so that first and second walls cross in a geometrical projection through the separation wall. The term inversion means that the second flow structure is a mirror shape relatively to the first flow structure. For example, the second flow structure can be obtained by 180° rotation about an axis perpendicular to the separation plate.

The separation wall comprises a pattern of openings through the separation wall, the openings connecting the first volume with the second volume. An opening of the pattern of openings is provided at each of the concave portion. Furthermore, the undulating first walls of the first flow structure and the inverted undulating second walls of the second flow structure in combination with the openings in the separation wall are arranged such that each opening is adjacent to both one of the first concave portions in one of the first channels on the first side of the separation wall, and thus in the first volume, and adjacent to one of the second concave portions in one of the second channels on the second side of the separation wall, and thus in the second volume. Due to the fact that the one of the second concave portions at the opening is inverted relatively to the one of the first concave portions at the same opening, the opening is having the two concave portions on opposite sides of the opening. Accordingly, a flow of coolant is achieved between one of the first channels and one of the second channels through the respective opening.

The flow structures with the undulating walls and channels are arranged for flow of coolant from the first end to the second end and flow of coolant from the second end to the first end in multiple subsequent repetitive coolant flow periods. Each of such periods includes flow from the second volume through a first opening into a first one of the first flow channels in the first volume, then flow inside and along this channel towards the second end and to a second opening in this channel, then through the second opening into one of the second channels in the second volume and further forward towards the second end in this channel to a third opening for flow through the third opening back into the first volume Such flow period through a first portion of first and second flow channels is repeated until reaching the second end.

In a wide sense, a this resembles a side-by-side array of helical flow structures, although, having an additional advantage of thorough mixing of coolant with coolant from neighbouring openings when flowing along the channels.

Furthermore, coolant flows along the second flow path in similar coolant flow periods, however, oppositely directed from the second end towards the first end. In order to achieve two oppositely directed flow paths, the second flow path involves a second portion of the first and second channels which is different from a first portion of the first and second channels. For example, the forward flow path involves every second of the first channels and every second of the second channels and the return flow path involves remaining channels in between. The term “involves” has to be understood as the flow path being, or in other words proceeding or extending, through the respective portions of the channels.

Advantageously, the first walls are shaped identical and arranged equidistant with a first distance X1 when measured along the flow paths, and the second walls are shaped identical and also arranged equidistant with the same distance X1.

As consequence, the openings in the separation wall are arranged equidistant in the averaged first flow direction with the first distance X1. Advantageously, the openings in the separation wall are equidistant in the lateral direction with a second distance X2. For example, X1=X2.

Typically, the first structure comprises at least six first channels, which implies at least three of the above-described periods for the flow path, however, typically more, such as at least nine first channels.

For good mixing and for providing a width with good uniformity in temperature, each channel comprises at least four openings, but typically more, such as more than six, however, in most cases not more than twenty.

Although not strictly necessary, a simple construction is found when the separation wall is plane and parallel to the first coolant chamber wall.

Optionally, the first flow structure is integral with the first coolant chamber wall. For example, the first flow structure and the first coolant chamber wall are formed out of a single piece of material. As an option, the first flow structure and the first coolant chamber wall is a single forged metal block. Metal forging under high pressure is a fast production method, and due to the first coolant chamber wall and the first flow structure being a single metal piece, where the metal is thermally conducting, good thermal con-ductivity is provided from the coolant chamber wall to the coolant.

As an alternative to metal forging, moulding of metals or other thermally conducting materials, such as thermally conducting polymers, is useful or sintering of thermally conductive ceramics

Simulations have illustrated that a temperature homogeneity of DT<1K can be achieved for electronics that comprise three half-bridge modules, where each module comprises 4-12 semiconductor chips. This temperature homogeneity is substantially better than a typical pin fin cooler, which has DT in the range of 10-15K under typical load conditions.

The cooling device is useful in particular for cooling power electronics in an electric vehicle (EV), for example cooling power modules, converters and/or inverters.

Typical dimensions of the cooling module are 50-250 mm×50-250 mm×5-30 mm for automotive applications.

For example, dimensions of a cooling device, when used for a personal electric vehicle, are approximately 200 mm×60 mm×15 mm.

For renewable energy applications, such as the power electronics in wind turbines where several MW are processed or off-road electric vehicles for example mining the cooling device dimension will be on the order of 200-800 mm×200-800 mm×20-80 mm.

Although, the device is particularly useful for vehicles, it is of more general char-acter and can also be advantageous for use in an industrial machine for cooling electronic components. Another advantageous use is in a wind turbine for cooling electronic components.

### BRIEF DESCRIPTION OF THE DRAWINGS

The invention will be explained in more detail with reference to the drawing, where

FIG. 1A illustrates a cooling device in perspective view;

FIG. 1B illustrates the cooling device of FIG. 1A in a different perspective view;

FIG. 1C illustrates the cooling device of FIG. 1A in an exploded view;

FIG. 1D illustrates the first cooling chamber wall and first flow structure;

FIG. 2 is a transparent view through a middle separation wall of the cooling device;

FIG. 3 shows a view perpendicular onto a middle separation wall;

FIG. 4A illustrates an array of coolant modules in perspective view;

FIG. 4B illustrates the array of FIG. 4A in an exploded view;

FIG. 4C illustrates the array of FIG. 4A in a different exploded view;

FIG. 4D illustrates the array of FIG. 4A in a cross sectional view.

### DETAILED DESCRIPTION

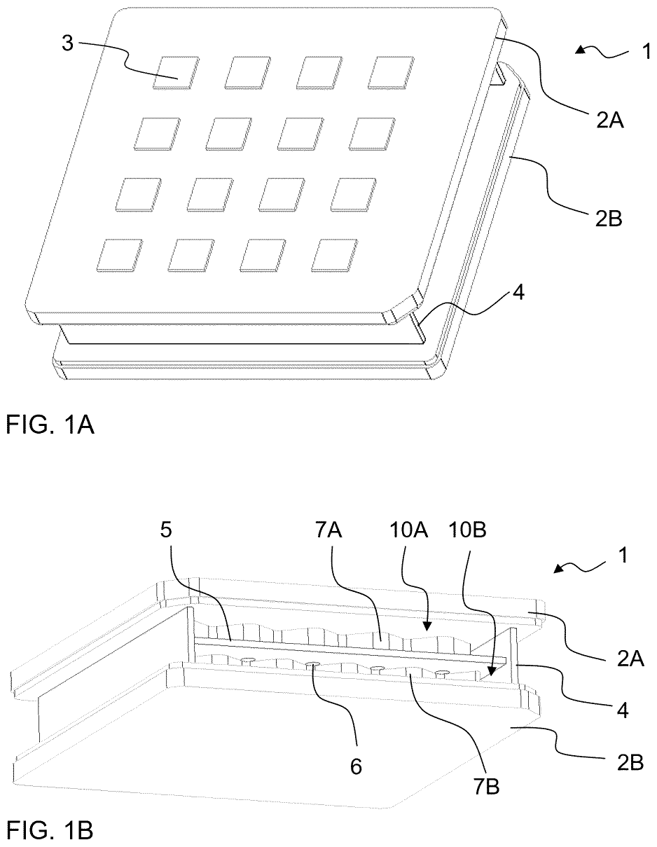

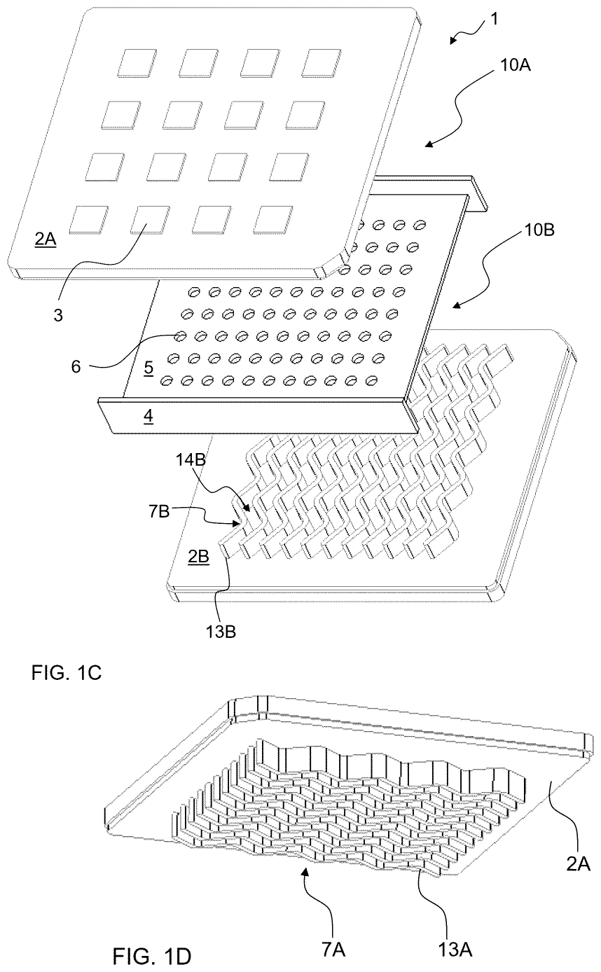

FIG. 1A is a perspective view of a cooling device 1, for example a cooling module in an array of modules, for cooling electronic components 3 on at least one of its outer surfaces, optionally both surfaces.

As illustrated in FIG. 1B, the cooling device 1 has a sandwich structure of a first coolant chamber wall 2A and a second coolant chamber wall 2B, as well as a separation wall 5 centred in between the coolant chamber walls 2A, 2B. Between the first coolant chamber wall 2A and the separation wall 5 and delimited by side walls 4, there is provided a first volume 10A in which there is arranged a first flow structure 7A for directed flow of coolant through the first volume 10A. Between the second coolant chamber wall 2B and the separation wall 5 and delimited by the side walls 4, there is provided a second volume 10B in which there is arranged a second flow structure 7B for flow of the coolant through the second volume 10B. The separation wall 5 comprises multiple openings 6 through which the coolant is flowing alternatingly back and forth between the first volume 10A and the second volume 10B as guided by the corresponding flow structures 7A, 7B, which will be explained in detail below.

FIG. 1C is an exploded view of the cooling device 1. As illustrated, the second flow structure 7B is adjacent to the second coolant chamber wall 2B. In the presented exemplified embodiment, the second flow structure 7B is connected to the inner side of the second coolant chamber wall 2B, which is facing the second volume 10B.

For example, the second flow structure 7B is integral with the second coolant chamber wall 2B, and, optionally, the first flow structure 7A is integral with the first coolant chamber wall 2A.

A possible production method that can be used for producing the flow structure 7A, 7B as integral with the corresponding coolant chamber wall 2A, 2B, is impact extrusion, also called forging, in which a stamp with a template matrix by high pressure impact deforms a metal block into the desired shape. Alternatively, the second coolant chamber wall 2B and the second flow structure 7B are produced by moulding or sintering, for example thermally conductive polymers or ceramics. A similar production method can be used for the first coolant chamber wall 2A and first flow structure 7A.

Important is that the first coolant chamber wall 2A that is used for cooling of the electronics is thermally conductive in order for the first coolant chamber wall 2A to take up thermal energy from the electronics 3 on the outer side of the first coolant chamber wall 2A and transfer the heat to the coolant flowing in the first volume 10A along the inner side of the first coolant chamber wall 2A.

If there are electronic components 3 also provided on the outer side of the second coolant chamber wall 2B, also this needs to be thermally conductive.

The second flow structure 7B comprises multiple undulating walls 13B with flow channels 14B in between. The separation wall 5 comprises multiple openings 6, which are located at concave portions of the undulating walls 13B. As illustrated in FIG. 1D, a corresponding but inverted first flow structure 7A with undulating walls 13A is adjacent the first coolant chamber wall 2A.

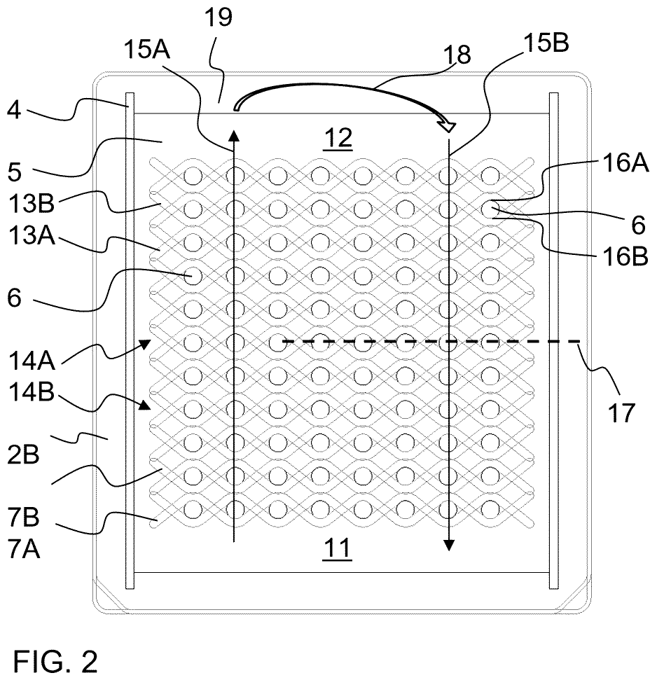

FIG. 2 illustrates a transparent view through the separation wall 5, showing the first flow structure 7A with its first undulating walls 13A overlaid the second flow structure 7B with its second undulating walls 13B, which are inverted relatively to the first undulating walls 13A. Openings 6 are provided in the separation wall 5. As clearly ob-served, the openings 6 are located at each concave portions 16A, 16B of the first and second undulating walls 13A, 13B.

The undulating walls 13A, 13b of the first and second flow structures 7A,7B, as well as the openings 6 in the separation wall 5 are arranged such that the coolant flows into the second volume 10B at a first end 11 of the flow structures 7A, 7B and alternates through the openings 6 as guided by the undulating first and second channels 14A, 14B along a first average path 15A until it reaches the second end 12 of the flow structures 7A, 7B, however in the first volume 10A, then flows from the first volume 10A into the second volume 10A at the second end 12, as illustrates by arrow 18, and reverses into a reverse path 15B flowing back to the first end 11 in the first volume 10A. Thus, at the first end 11, the first volume 10A and the second volume 10B are separated and function as outlet and inlet, respectively, for the coolant, while at the second end 12, the first and second volume are connected by connecting passage 19 for flow of coolant from the first volume 10A to the second volume 10B for the reverse flow.

Alternatively to the coolant changing direction at the second end 12, the device 1 is provided with two coolant inlets and two coolant outlets at the opposite ends 11, 12, so that a first portion of coolant is flowing from a first coolant inlet into the second volume 10B at the first end 11 and after flow along the first flow path 15A leaving the first volume 10A at the second end 12 through a first coolant outlet, while a different portion of coolant is flowing from a second coolant inlet into the second volume 10B at the second end 12 and after flow along the second flow path 15B leaving the first volume 10A at the first end 11 through a second coolant outlet. In this case, no connecting passage 19 is provided and the separation wall 5 at the second end 12 sealed by a gasket that is separating the first volume 10A from the second volume 10B.

As indicated by the line 17 in FIG. 2, each the first and second undulating walls 13A, 13B have an averaged wave-form direction 17 that is perpendicular to the first and second flow paths 15A, 15B. However, the averaged wave-form direction 17 may deviate slightly from the exact perpendicular direction, for example deviating by an angle in the range up to 10° from perpendicular, which implies an angle of 80° to 90° to the first and second flow paths. In alternative embodiments, the deviation from perpendicular is in the range of 0° to 20°, 0° to 30°, 10° to 20°, 10° to 30° or 20° to 30°.

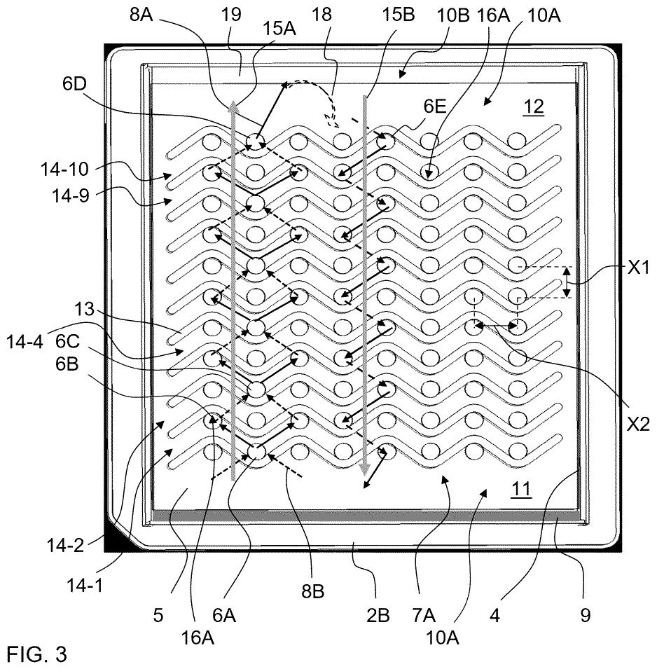

With reference to FIG. 3, the flow paths 15A, 15B are explained in more detail. Stippled arrows 8B illustrate flow in the second volume 10B, which in the illustration in FIG. 3 is underneath the separation wall 5 and for which the channels 14B are not visible in FIG. 3, in contrast to the illustration of FIG. 2. Solid arrows 8A illustrate flow in the first volume 10A, which in the illustration of FIG. 3 is above the separation wall 5 and for which the first undulating walls 13A and correspondingly wave-formed first channels 14A are visible.

The first flow path 15A starts with flow of coolant from the second volume 10B, underneath the separation wall 5, upwards through the first openings 6A in the first illustrated channel 14-1. Inside the first illustrated channel 14-1, the coolant flows forward towards the second end 12 under an angle, for example in the range of 25° and 65°, optionally in the range og 40° to 50° with the averaged first and second flow paths 15A, 15B (see FIG. 2). The coolant is then stopped by the concave portion 16A of the first illustrated channel 14-1 and flows downwards through openings 6B into the second volume 10B. Continuing this flow pattern along the forward path 15A, the coolant undulates along multiple quasi-helical flow path sections from the first channel 14-1 through the third, fifth, seventh, and ninth channel 14-9 towards the opposite end 12, while being subject to thorough mixing on its path.

At the second end 12, the coolant exits through the last opening 6D in the first volume 10A and flows through connecting passage 19 from the first volume 10A to the second volume 10B and flows underneath the separation wall 5 to the first return opening 6E and then upwards through the first return opening 6E and follows a second flow path 15B back to the first end 11, where it ends in the first volume 10A. While following this second flow path 15B, the coolant flows in the tenth channel 14-10, and then through the eighth, sixth, fourth and second channel 14-2, and only through channels 14A with even numbers, 14-10 through 14-2, but not the channels 14A with the uneven numbers, 14-1 through 14-9.

At the first end 11, the first volume 10A and the second volume 10B are separated by a gasket 9 so that the second volume 10B at the first end 11 functions as coolant inlet, and the first volume 10A at the first end 11 functions as coolant outlet.

Due to the forward path 15A through the channels 14-1 to 14-9 of uneven numbers and the return path 15B through channels 14-10 to 14-2 of even numbers in the first volume 10A (above the separation wall 5), and vice versa in the second volume 10B (below the separation wall 5), a high degree of temperature equalization is obtained. The effect of the flow of the coolant on its forward path 15A and the flow of the coolant on its return path 15B resembles the effect of double-helical paths, best seen in the illustration of a portion of the return path 15B in FIG. 3, although knowing that all openings 6 in a channel 14A work simultaneously. Compared to double-helical flow paths, the illustrated configuration not only maintains the advantages of double helical flow paths in cooling systems but adds further advantages. One additional advantage is a more thorough mixing of the coolant so that a higher cooling efficacy is obtained. Another advantage, which is important to notice is the following. If one of the openings 6 happen to get clogged and prevents flow, the other openings 6 compensate for the missing flow through the clogged opening 6, and the flow returns to the normal pattern in the subsequent channels 14A, 14B. This is very different for double helical paths, as a clogging of the flow path stops the cooling functioning of the entire double helical flow path. Accordingly, the exemplified system is superior over double helical flow paths by not only providing the same advantages but by adding further advantages.

In analogy to triple-helical flow paths with a forward, reverse and second forward flow path, a similar arrangement can also be achieved with the system as described herein. In such embodiment, the channels 14A, 14B in the first and second flow structures 7A, 7B on opposite sides of the separation wall 5 and the openings 6 in the separation wall 5 would be arranged such that the coolant would flow from the first illustrated channel 14-1 downwards into a channel 14B of the second flow structure 7B and flow upwards through an opening 6 in the fourth illustrated channel 14-4, then down again and up into the seventh channel, and so forth until the second end 12, then reverse direction and flow back until reaching the second channel 14-2, then reversing direction into a second forward flow from the third channel to the sixth channel and further to the ninth channel 14-9 towards the second end 12, at which also the coolant outlet would be arranged.

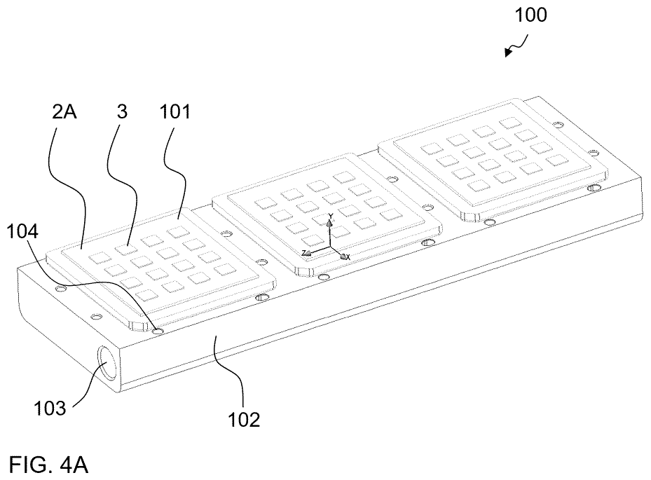

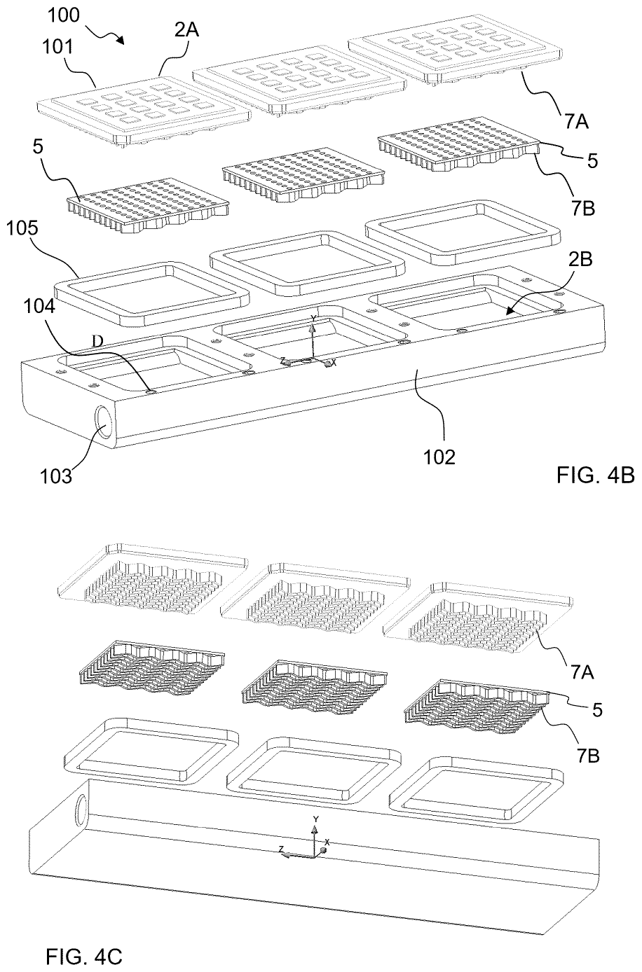

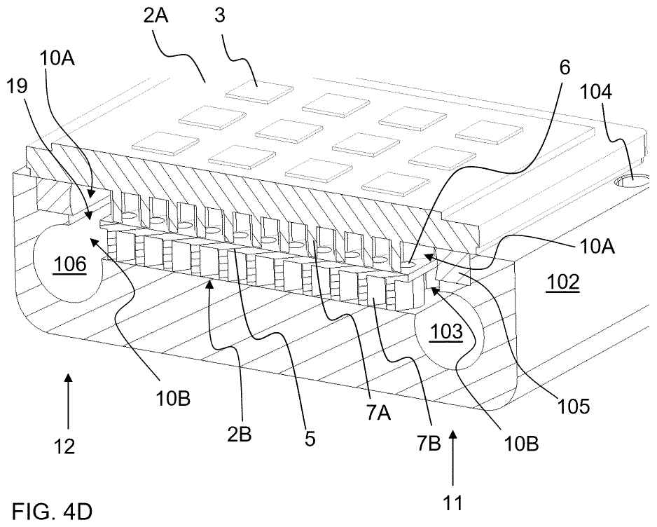

FIG. 4A in perspective view, and FIGS. 4B and 4C in exploded view and in FIG. 4D in cross sectional view, illustrate a cooling device 100 with an array of cooling modules 101 mounted inside a manifold housing 102. Each of the cooling modules 101 is to a large extent similar to the cooling device of FIG. 1 but does not comprise a different second cooling chamber wall 2B, which in this embodiment instead is substituted part of the manifold housing 102. It comprises a first coolant chamber wall 2A, similar to the first coolant chamber wall 2A in FIG. 1 with a first flow structure 7A adjacent to the first coolant chamber wall 2A, for example attached to or integral with the first coolant chamber wall 2A. However, the second flow structure 7B, which is adjacent the opposite side of the separation wall 5, relatively to the first flow structure 7A, is not attached to any second coolant chamber wall, as this is absent in the module 101.

Optionally, the second flow structure 7B is attached to the separation wall 5, for example glued to the separation wall for ease of mounting and sealing. Alternatively, the second flow structure 7B is integral with the separation wall 5, as better seen in the cross sectional drawing in FIG. 4D.

A gasket 105 seals around the separation wall 5, especially separates the first volume 10A from the second volume 10B at the first end 11, the necessity of which was explained in connection with the gasket 9 in FIG. 3.

The role of the gasket 105 is better seen in the cross sectional drawing in FIG. 4D. Similar to the drawing in FIG. 1B, the drawing in FIG. 4D illustrates a first volume 10A with the first flow structure 7A above the separation wall 5 and a second flow volume 10B below the separation wall 5. From the inlet 103, coolant flows into the second flow structure 7B in the second volume 10B at the first end 11 and through the opening 6 upwards into the first flow volume 10A. The flow path towards the opposite second end 12 is similar as illustrated in FIG. 3. At the opposite second end 12, a reverse channel 106 receives the coolant from the first volume 10A through the passage 19, and the reverse flow starts in the second volume 10B, as already explained in connection with FIG. 3. The reverse flow ends at the first end 11 in the first volume 10A, which is separated from the second volume 10B by the gasket 105 at this first end 11, and from which the coolant is leaving the manifold 102 through coolant outlet 104.

In the alternative embodiment where the flow is not reversed at the second end 12, but two independent flows provided, one from the first end 11 to the second end 12 and one from the second end 12 to the first end 11, the gasket 105 would seal against the separation wall 5 also at the second end 12.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A cooling device for cooling electronic components in thermal contact with an outer side of a thermally conducting first coolant chamber wall; wherein the cooling device comprises an inner volume between an inner side of the first coolant chamber wall and an opposite second coolant chamber wall with flow paths for a coolant through the inner volume for cooling the first coolant chamber wall;
wherein a separation wall divides the inner volume into a first volume between the separation wall and the first coolant chamber wall and a second volume between the separation wall and the second coolant chamber wall, wherein the separation wall comprises a pattern of openings through the separation wall connecting the first volume with the second volume;
wherein a first flow structure is provided only in the first volume and sealingly connected to the first side of the separation wall and to the first coolant chamber wall, and a second flow structure is provided only in in the second volume and sealingly connected to the second side of the separation wall and to the second coolant chamber wall, so as to sandwich the separation wall by the first and second flow structures;
wherein the flow path comprises an averaged first flow path in a first, forward direction along the first coolant chamber wall from a first end to a second, opposite end of the flow structures;
wherein the flow path comprises an averaged second flow path in a second, opposite direction along the first coolant chamber wall from the second end to the first end for uniform cooling of the first coolant chamber wall by the combination of the flow of coolant along the mutually opposite first and the second flow paths;
wherein the first flow structure comprises an array of multiple side-by-side placed first undulating walls, each of which has an alternating wave-form with first concave portions, wherein the array of first undulating walls in combination with the first coolant chamber wall and the separation wall define a first array of multiple undulating first channels with a corresponding alternating wave-form in the first volume, and wherein the second flow path structure comprises an array of multiple side-by-side placed second undulating walls, each of which has an alternating wave-form with second concave portions, wherein the array of second undulating walls in combination with the second coolant chamber wall and the separation wall define a second array of multiple undulating second channels with a corresponding alternating wave-form on the separation wall in the second volume, wherein each the first and second undulating walls have an averaged wave-form direction that is perpendicular to the first and second flow paths, and wherein the first flow structure is geometrically inverted relatively to the second flow structure so that first and second walls cross in a geometrical projection through the separation wall;
wherein the separation wall comprises an opening of the pattern of openings provided at each of the concave portions, each opening being adjacent to both one of the first concave portions and one of the second concave portions, where the second concave portion is inverted relatively to the one first concave portion, for flow of coolant between one of the first channels and one of the second channels through the respective opening;
wherein the flow structures are arranged for flow of coolant from the first end to the second end and flow of coolant from the second end to the first end in multiple subsequent coolant flow periods, each of such periods including flow from the second volume through a first opening into a first one of the first channels in the first volume, flow along this channel towards the second end and to a second opening in this channel, then through the second opening into one of the second channels in the second volume and further forward towards the second end in this channel to a third opening for flow through the third opening back into the first volume, repeating this coolant flow period through a first portion of first and second channels until reaching the second end, and arranged for coolant flow along the second flow path in similar coolant flow periods directed towards the first end;
wherein the second flow path is through a second portion of the first and second channels which is different from a first portion of the first and second channels.

2. The cooling device according to claim 1, wherein the forward-directed first flow path is through every second of the first channels and every second of the second channels and the return-directed second flow path is through remaining channels in between.

3. The cooling device according to claim 1, wherein the second flow path is a continuation of the first flow path after flow from one to the other of the two volumes at the second end and change of direction of the coolant from first flow path to the second flow path towards the first end with a flow in similar coolant flow periods directed towards the first end.

4. The cooling device according to claim 1, wherein the first undulating walls are shaped identical and arranged equidistant with a first distance X1 and the second undulating walls are shaped identical and arranged equidistant with the same distance X1.

5. The cooling device according to claim 1, wherein the opening are arranged equidistant in the flow direction with a first distance X1, or equidistant in the lateral direction with a second distance X2 or both.

6. The cooling device according to claim 1, wherein the first structure comprises at least six first channels.

7. The cooling device according to claim 1, wherein each channel comprises at least four openings.

8. The cooling device according to claim 1, wherein the separation wall is plane and parallel to the first coolant chamber wall.

9. The cooling device according to claim 1, wherein the first flow structure is integral with the first coolant chamber wall.

10. The cooling device according to claim 9, wherein the first flow structure and the first coolant chamber wall is formed out of a single piece of material.

11. The cooling device according to claim 10, wherein the first flow structure and the first coolant chamber wall is a single forged metal block.

12. Use of a cooling device according to claim 1 in an electrical vehicle for cooling electronic components used for power regulation of electrical propulsion motors.

13. A method of operating a cooling device according to claim 1, the method comprising causing flow of coolant from the first end to the second end and flow of coolant from the second end to the first end in multiple subsequent coolant flow periods, each of such periods including flow from the second volume through a first opening into a first one of the first channels in the first volume, flow along this channel towards the second end and to a second opening in this channel, then through the second opening into one of the second channels in the second volume and further forward towards the second end in this channel to a third opening for flow through the third opening back into the first volume, repeating this coolant flow period through a first portion (of first and second flow channels until reaching the second end, and arranged for coolant flow along the second flow path in similar coolant flow periods directed towards the first end, wherein the second flow path is through a second portion of the first and second channels which is different from a first portion of the first and second channels.

14. The method according to claim 13, wherein the second flow path is a continuation of the first flow path and the method comprises causing flow of coolant from one to the other of the two volumes at the second end and changing direction of the coolant from first flow path to the second flow path towards the first end with a flow in similar coolant flow periods directed towards the first end.

15. The method according to claim 13,
wherein the first flow path from the first end to the second end is through every second of the first channels and every second of the second channels and wherein the second flow path from the second end to the first end is through remaining channels in between every second of the first and second channels;
wherein the first walls are shaped identical and arranged equidistant with a first distance X1 and the second walls are shaped identical and arranged equidistant with the same distance X1;
wherein the openings are arranged equidistant with a first distance X1 in the flow direction, and equidistant with a second distance X2 in the lateral direction with a second distance X2;
wherein the first structure comprises at least six first channels;
wherein each channel comprises at least four openings;
wherein the separation wall is plane and parallel to the first coolant chamber wall;
wherein the method further comprises causing flow of the coolant through at least three flow periods towards the second end.
